(19) United States
(12) Patent Application Publication
(10) Pub. No.: US 2026/0113055 A1
(43) Pub. Date: Apr. 23, 2026

(54) DETECTION CIRCUIT AND SIGNAL COMPRESSION METHOD

(71) Applicant: Japan Display Inc., Tokyo (JP)

(72) Inventors: Tomoyuki ISHIHARA, Tokyo (JP); Naoki TAKADA, Tokyo (JP)

(21) Appl. No.: 19/359,140

(22) Filed: Oct. 15, 2025

(30) Foreign Application Priority Data
Oct. 17, 2024 (JP) 2024-181819
Jul. 16, 2025 (JP) 2025-119435

(51) Int. Cl. H03M 7/30

(52) U.S. Cl. CPC H03M 7/30

(57) ABSTRACT

The amount of data sent in a unit time is reduced in a case of transmitting sensor data by using a transmission system involving band limitation.

A detection circuit includes a plurality of detection elements, a plurality of scanning lines connected to a scan circuit, a plurality of signal lines connected to a detection circuit, and a control circuit. Each of the plurality of detection elements is connected to the corresponding scanning line and the corresponding signal line. The detection circuit is configured to sequentially read out detection values of signals of the plurality of detection elements through the plurality of signal lines. When a detection value of a signal of a detection element of interest is externally output, the control circuit outputs, as transmission difference data, difference data between a value based on a detection value of a signal of a detection element read out before the detection timing of the detection value of the signal of the detection element of interest and the detection value of the signal of the detection element of interest.

### CLAIM OF PRIORITY

The present application claims priority from Japanese Patent Application JP 2025-119435 filed on Jul. 16, 2025 and Japanese Patent Application JP 2024-181819 filed on Oct. 17, 2024, the contents of which are hereby incorporated by reference into this application.

### BACKGROUND OF THE INVENTION

### (1) Field of the Invention

The present disclosure relates to a detection circuit and a signal compression method.

### (2) Description of the Related Art

For example, JP-2012-129805-A has been proposed as a wireless network system that transmits sensor data.

### SUMMARY OF THE INVENTION

The present discloser has found that, in a case of transmitting sensor data by using, for example, a transmission system involving band limitation, such as wireless communication, the amount of data sent in a unit time is large and the transmission band becomes insufficient.

An object of the present disclosure is to provide a technique that can reduce the amount of data sent in a unit time, in a case of transmitting sensor data by using a transmission system involving band limitation.

Other problems and novel features will become clear from description of the present specification and accompanying drawings.

A simple description of the outline of representative configurations in the present disclosure is as follows.

Specifically, a detection circuit according to an aspect of the present disclosure includes: a plurality of detection elements arranged in a matrix form; a plurality of scanning lines that extend in a first direction and are arranged in a second direction intersecting the first direction, the scanning lines being connected to a scan circuit; a plurality of signal lines that extend in the second direction and are arranged in the first direction, the signal lines being connected to a detection circuit; and a control circuit, in which each of the plurality of detection elements is connected to a corresponding scanning line and a corresponding signal line, the detection circuit is configured to sequentially read out detection values of signals of the plurality of detection elements through the plurality of signal lines, and the control circuit, when externally outputting a detection value of a signal of a detection element of interest, outputs, as transmission difference data, difference data between a value based on a detection value of a signal of a detection element read out before a detection timing of the detection value of the signal of the detection element of interest and the detection value of the signal of the detection element of interest.

Further, a signal compression method according to another aspect of the present disclosure is a signal compression method for a detection value (detection data) of a detection circuit in which a plurality of detection elements are arranged in a matrix form, the signal compression method including: executing first computation of first data encoded on the basis of a difference in a detection value of a signal from corresponding one line in a previous frame in units of one line in a current frame; executing second computation of second data encoded on the basis of a difference from an average in a predetermined range in the current frame; and selecting one data with a smaller data amount from either the first data or the second data.

### BRIEF DESCRIPTION OF THE DRAWINGS

FIG. 1 is a diagram depicting an overall configuration of a sensor system including a detection circuit and a host apparatus according to an embodiment;

FIG. 2 is a diagram depicting a configuration example of a sensor array of the detection circuit in FIG. 1;

FIG. 3 is a diagram for explaining a first example of an encoding method according to the embodiment;

FIG. 4 is a diagram for explaining a second example of the encoding method according to the embodiment;

FIG. 5 is a diagram for explaining a third example of the encoding method according to the embodiment;

FIG. 6 is a diagram for explaining a fourth example of the encoding method according to the embodiment;

FIG. 7 is a diagram for explaining a data format according to the embodiment;

FIG. 8 is a block diagram of an encoding circuit according to the embodiment;

FIG. 9 is a block diagram of a decoding circuit according to the embodiment;

FIG. 10 is a flowchart for explaining an encoding procedure according to the embodiment;

FIG. 11 is a flowchart for explaining difference value encoding processing in FIG. 10;

FIG. 12 is a diagram for explaining a fifth example of the encoding method according to a modification;

FIG. 13 is a diagram for explaining a data format according to the modification;

FIG. 14 is a diagram for explaining a configuration example of a consecutiveness compression unit according to the modification; and

FIG. 15 is a flowchart for explaining an encoding procedure according to the modification.

### DETAILED DESCRIPTION OF THE PREFERRED EMBODIMENT

An embodiment of the present disclosure is described below with reference to the drawings. The disclosure is merely an example absolutely, and what can be easily conceived by those skilled in the art concerning an appropriate change with keeping of the gist of the disclosure is naturally included in the scope of the present disclosure. Further, in some cases, the drawing is schematically represented concerning the width, thickness, shape, and the like of each portion compared with an actual mode in order to make the description clearer. However, such a drawing is absolutely an example and does not limit interpretation of the present disclosure. Moreover, in the present specification and each diagram, an element similar to an element described previously concerning an already-given diagram is given the same numeral, and detailed description thereof is sometimes omitted as appropriate.

### Embodiment

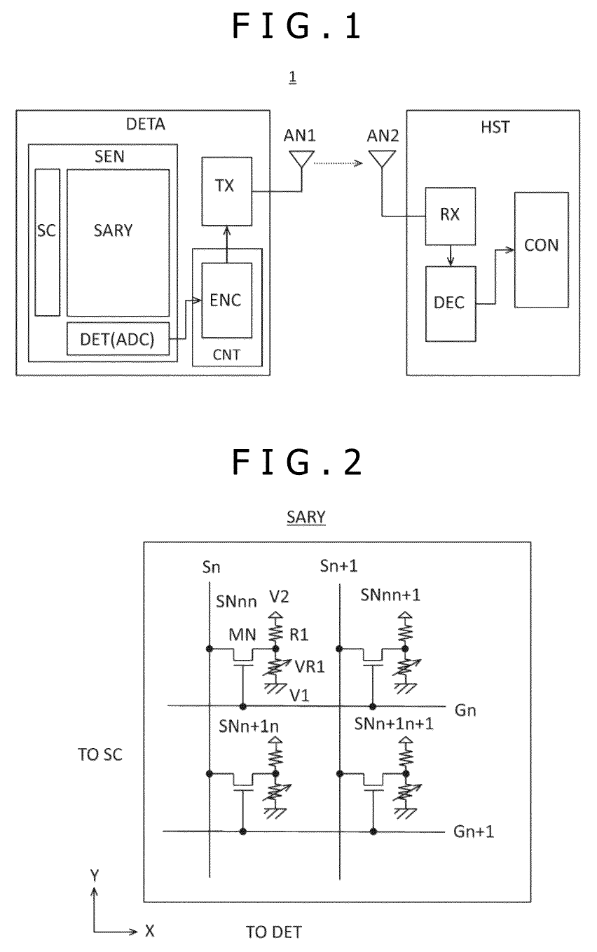

First, a sensor system including a detection circuit and a host apparatus is described with use of FIGS. 1 and 2. FIG. 1 is a diagram depicting an overall configuration of the sensor system including the detection circuit and the host apparatus according to the embodiment. FIG. 2 is a diagram depicting a configuration example of a sensor array of the detection circuit in FIG. 1.

As depicted in FIG. 1, a sensor system 1 includes a detection circuit DETA and a host apparatus HST. The detection circuit DETA includes a sensor unit SEN, a control circuit CNT, a transmitting circuit TX, and a transmitting antenna AN1. The sensor unit SEN includes a sensor array SARY, a scan circuit (scanning circuit) SC, and a detection circuit DET including an analog-to-digital conversion circuit ADC.

As depicted in FIG. 2, the sensor array SARY includes a plurality of detection elements SN (SNnn, SNnn+1, SNn+1n, and SNn+1n+1) arranged in a matrix form (form of rows and columns) in a first direction X and a second direction Y intersecting the first direction X. The sensor array SARY includes also a plurality of scanning lines G (Gn and Gn+1) that extend in the first direction X and are arranged in the second direction Y intersecting the first direction X and are connected to the scan circuit SC, and a plurality of signal lines S (Sn and Sn+1) that extend in the second direction Y and are arranged in the first direction X and are connected to the detection circuit DET. In this example, the sensor array SARY with a matrix form of two rows×two columns is exemplified. The matrix of the sensor array SARY may be made into, for example, a configuration of 80 rows×80 columns.

The plurality of detection elements SN are, for example, pressure detection elements used for a pressure sensor that detects the pressure. Each of the plurality of detection elements SN is made into the same configuration. In the following, a configuration of the detection element SNnn is described as a representative example. The detection element SNnn includes a variable resistive element VR1, a resistive element R1, and a thin film transistor MN. The variable resistive element VR1 and the resistive element R1 are connected in series between, for example, a first reference potential V1 as a ground potential GND such as 0 V (zero volts) and a second reference potential V2 such as a supply potential VDD. An N-channel MOS semiconductor element is employed as the thin film transistor MN. The thin film transistor MN includes a gate electrode connected to the scanning line Gn and a source-drain channel connected between a common connecting node between the variable resistive element VR1 and the resistive element R1 and the signal line Sn. In the detection element SNnn, the thin film transistor MN is turned to an ON-state when the scan circuit SC sequentially scans the plurality of scanning lines Gn and Gn+1 and the scanning line Gn is set to a selection level. At this time, the potential of the common connecting node between the variable resistive element VR1 and the resistive element R1 is transmitted to the signal line Sn as a detection signal of the detection element SNnn, and is then converted from an analog voltage signal to a detection value of a digital voltage signal (detection value of the detection signal of the detection element SNnn) by the analog-to-digital conversion circuit ADC connected to the signal line Sn. In this example, an active matrix system is described as the system of the sensor array SARY. However, a passive matrix system may be employed. In the passive matrix system, a resistive component attributed to a gate signal is not made independent. Thus, the influence of wraparound or the like of the resistive component adjacent in the second direction Y is likely to occur, and there is a possibility that increasing the resolution becomes difficult. Thus, it is preferable to employ the active matrix system, which allows increase in the resolution, as the system of the sensor array SARY.

The scan circuit SC sequentially scans the plurality of scanning lines G. Thus, in the plurality of detection element SN in the sensor array SARY with the matrix form, operation of supply of the detection signals of a plurality of detection elements connected to one scanning line to the analog-to-digital conversion circuit ADC through the signal lines S is sequentially executed with change of the one scanning line. Thereby, the detection signals of the plurality of detection elements SN in the sensor array SARY are sequentially converted to the detection value of the digital voltage signal by the analog-to-digital conversion circuit ADC.

The control circuit CNT has an encoding circuit ENC that encodes the detection value of the digital voltage signal converted by the analog-to-digital conversion circuit ADC.

The transmitting circuit TX is configured to receive an encoded signal transmitted by the encoding circuit ENC, and converts the received encoded signal to a wireless signal to transmit it from the transmitting antenna AN1. That is, the encoded signal is transmitted by using a transmission system involving band limitation, such as wireless communication using the transmitting antenna AN1.

The host apparatus HST includes a receiving antenna AN2, a receiving circuit RX, a decoding circuit DEC, and a host control section CON. The receiving antenna AN2 receives the wireless signal from the transmitting antenna AN1. The receiving circuit RX is connected to the receiving antenna AN2, and converts the received wireless signal to the encoded signal. The decoding circuit DEC decodes the converted encoded signal to convert the encoded signal to the detection value of the digital voltage signal. The host control section CON processes the detection value of the digital voltage signal obtained by the conversion to process the detection value obtained by the detection by the sensor unit SEN. Further, the host control section CON executes desired processing on the basis of the detection value obtained by the detection by the sensor unit SEN.

As described above, in a case of transmitting the sensor data by using, for example, the transmission system involving band limitation, such as the wireless communication, the amount of data sent in a unit time is large and the transmission band becomes insufficient. Thus, contrivance is required to be made for the encoding system such that the amount of data sent in the unit time can be reduced as much as possible.

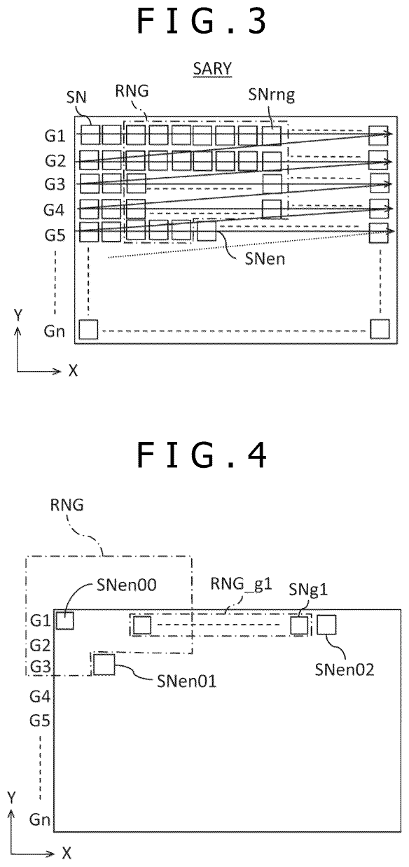

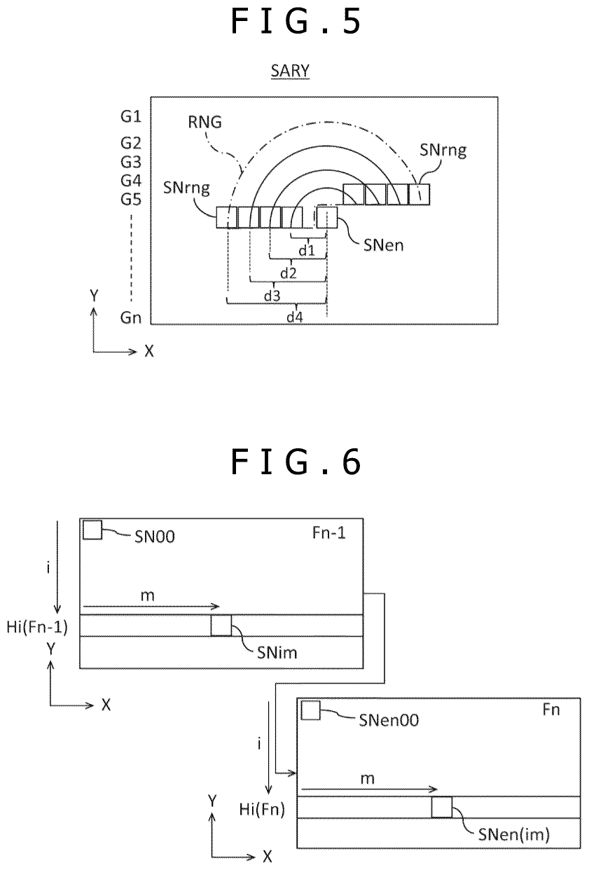

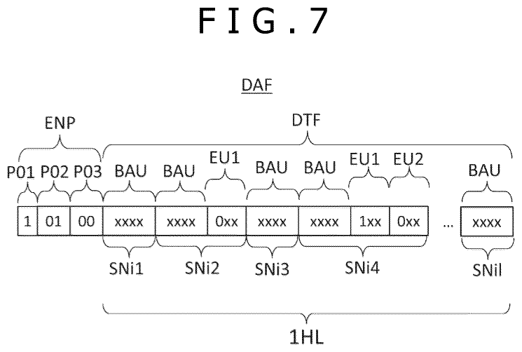

Next, an encoding method and a data format of an encoded signal are described with use of FIGS. 3 to 7. FIG. 3 is a diagram for explaining a first example of the encoding method according to the embodiment. FIG. 4 is a diagram for explaining a second example of the encoding method according to the embodiment. FIG. 5 is a diagram for explaining a third example of the encoding method. FIG. 6 is a diagram for explaining a fourth example of the encoding method according to the embodiment. FIG. 7 is a diagram for explaining the data format according to the embodiment. Here, a description is given assuming that, for example, a plurality of scanning lines (G1 to Gn) are disposed in the sensor array SARY. That is, it is assumed that the scanning lines from the scanning line G1 on the first row to the scanning line Gn on the n-th row are disposed in the sensor array SARY, and the scan circuit SC sequentially scans the scanning lines one by one from the scanning line G1 on the first row to the scanning line Gn on the n-th row as indicated by arrows in FIG. 3.

As depicted in FIG. 3, for the detection signals of the plurality of detection element SN arranged in a matrix form in the sensor array SARY, first the scanning line on the first row (G1) is set to a selected state, and the detection signals of the plurality of detection elements SN (G1) connected to the scanning line on the first row (G1) are read out. Next, the scanning line on the second row (G2) is set to the selected state, and the detection signals of the plurality of detection elements SN (G2) connected to the scanning line on the second row (G2) are read out. Such operation is executed for all of the plurality of scanning lines G (G1 to Gn). That is, the plurality of scanning lines G (G1 to Gn) are sequentially scanned one by one, and the values of the detection signals of the plurality of detection element SN corresponding to one frame are read out.

A reference value for setting a difference value of each detection element is required to be set such that decoding (inverse operation of encoding) of the detection value (absolute value) of a detection element of interest, SNen, can be executed on the basis of the detection value (absolute value) that has been already decoded in the decoding circuit DEC.

In the first example of the encoding method in FIG. 3, the reference value is set to an average value of the detection values of the respective detection elements SNrng in a reference range RNG defined in advance in rows on the upper side relative to the detection element SNen as the encoding target (referred to as detection element of interest) and in the left side relative to the detection element SNen on the same row as the detection element SNen.

As depicted in FIG. 4, in the second example of the encoding method, when a detection element of interest, SNen01, is a detection element of interest near the upper end of the sensor array SARY or a detection element of interest near the left end of the sensor array SARY, the reference range RNG protrudes from the region of the sensor array SARY, and thus is limited to a possible range. That is, in this case, the reference range RNG is set to protrude from the region of the sensor array SARY in some cases. When a detection element of interest, SNen00, is the detection element at the upper left of the region of the sensor array SARY, the reference value is absent. Thus, the absolute value of the detection value of the detection element of interest, SNen00, is recorded or described as it is in a data format DAF described with FIG. 7. Further, in a case of a detection element of interest, SN02, disposed on the beginning row (corresponding to the scanning line on the first row (G1)) of the sensor array SARY, in calculation of the reference value, a range of the detection elements SNg1 on the left side on the same row is regarded as a reference range RNG_g1 and an average value of the detection values of the respective detection elements SNg1 on the left side on the same row in the reference range RNG_g1 is employed.

As above, excluding the case in which the detection element of interest, SNen00, is the detection element at the upper left of the region of the sensor array SARY, as the difference value in the case of using the reference range RNG, a difference value (difference data) between a value (average value) based on the detection value of the signal of one or multiple detection elements read out before the detection timing of the detection value of the signal of the detection element of interest, SNen, and the detection value of the signal of the detection element of interest, SNen, is employed. In other words, the average value of the detection values of the signals of the plurality of detection elements in the reference range RNG is employed as the reference value, and the difference value between this reference value and the detection value of the signal of the detection element of interest, SNen, is recorded and transmitted as the data format. Due to this, a digital value with a smaller number of bits than the normal absolute value (digital data with the number of bits resulting from representing the detection value of the signal as it is) is obtained. Thus, an effect that the amount of data transmitted is reduced can be obtained.

The third example of the encoding method in FIG. 5 is a method in which weighted average is employed for calculation of an average value. As the average value, weighted average such as, for example, Gaussian distribution-like weighted average in which the detection element closer to the detection element of interest, SNen, in terms of the distance is weighted to a larger extent is more desirable than the simple average value. Due to this, the possibility that the difference value becomes small is high.

An example of the weighted average is conceptually described below.

$$Weighted average value A : A = S / W$$

$$Sum of weighting factors W : W = f ( d 1 ) + f ( d 2 ) + ... + f ( d 1 )$$

$$Weighted cumulative value Sv : Sv = f ( d 1 ) \times L 1 + f ( d 2 ) \times L 2 + ... + f ( d 1 ) \times L$$

$$Function of weighting factor : f ( dn ) ( n = 1 , 2 , ... , 1 )$$

d1, d2, . . . , d1: distance between the detection element of interest, SNen, and a reference detection element
L1, L2, . . . , L1: detection value of the reference detection element

An example of the function of the weighting factor (Gaussian distribution) can be expressed as follows.

$$f ( d ) = e \hat{} - ( d \hat{} 2 / 2 \cdot σ \hat{} 2 )$$

d: distance from the pixel of interest (d1, d2, . . . , d1, or the like)
e: base of natural logarithm
σ: spread parameter

Here, in FIG. 5, as an example, a case in which the distances between the detection element of interest, SNen, and the reference detection element are d1, d2, d3, and d4 is depicted. The reference range RNG includes a plurality of detection elements on the left side of the detection element of interest, SNen, on the same row (detection elements at the distance d1 to d4), and a plurality of detection elements that exist on rows previous to the row of the detection element of interest, SNen, (rows on the upper side) and are included in a region of a semicircle with a radius of the distance d4. The weighting factor f(d) is configured to be set larger for the detection element closer to the detection element of interest, SNen, in terms of the distance. The weighted average value A is used to obtain the difference data between the value of the weighted average of the detection values of the plurality of detection elements in the reference range RNG and the detection value of the signal of the detection element of interest, SNen.

The fourth example of the encoding method in FIG. 6 is an example in which data of the detection value in the previous frame is used as the reference value. In a case of an application with a comparatively less time change, the detection value of the signal of a detection element of interest, SNen(im), in a current frame Fn and the detection value of the signal of a detection element SNim disposed at the same position as the detection element of interest, SNen(im), in a previous frame Fn-1 may be employed as the reference value of difference computation. Here, the detection element disposed at the same position is defined as follows. When the detection element of interest, SNen(im), in the current frame Fn is defined as the detection element disposed at an m-th position from the left end on an i-th horizontal line (scan line) Hi in the current frame Fn, the detection element SNim disposed at the m-th position from the left end on the i-th horizontal line (scan line) Hi in the previous frame Fn-1 is regarded as the detection element disposed at the same position. The detection element SNim disposed at the same position as the detection element of interest, SNen(im), in the previous frame Fn-1 corresponds to the detection element from which the detection value has been read out before the detection timing of the detection value of the signal of the detection element of interest, SNen(im), and difference data between a value based on the detection value of the signal of the detection element SNim and the detection value of the signal of the detection element of interest, SNen(im), is used as transmission difference data.

As described with FIG. 6, in the case of using the difference from the previous frame Fn-1, even with the detection element SNen00 at the upper left end of the current frame Fn, a reference value based on the detection value of the detection element SN00 at the upper left end in the previous frame Fn-1 exists. Thus, original data that is the detection value of the detection element SNen00 is not required to be retained in the data format. Therefore, there is a possibility that the amount of data transmitted can be reduced.

That is, the detection circuit DETA includes the plurality of detection elements SN arranged in a matrix form, the plurality of scanning lines G that extend in the first direction X and are arranged in the second direction Y intersecting the first direction X and are connected to the scan circuit SC, the plurality of signal lines S that extend in the second direction Y and are arranged in the first direction X and are connected to the detection circuit DET, and the control circuit CNT. Each of the plurality of detection elements SN is connected to the corresponding scanning line (Gn, Gn+1) and the corresponding signal line (Sn, Sn+1). The detection circuit DET is configured to sequentially read out the detection values of the signals of the plurality of detection elements SN through the plurality of signal lines S. When the detection value of the signal of the detection element of interest, SNen, is externally output, the control circuit CNT outputs, as the transmission difference data, the difference data between the value based on the detection value of the signal of the detection element read out before the detection timing of the detection value of the signal of the detection element of interest, SNen, and the detection value of the signal of the detection element of interest, SNen. The transmission difference data is difference data obtained by collecting, in units of one line in the current frame, a plurality of differences when each of a plurality of detection elements included in the corresponding line is employed as the detection element of interest, SNen. When X lines exist in the current frame, the transmission difference data includes X pieces of difference data corresponding to the X lines. The detection timing of the detection value of the signal of the detection element of interest, SNen, may be rephrased into the timing of decoding of the detection value of the signal of the detection element of interest, SNen. That is, the difference data between the value based on the detection value of the signal of the detection element read out before the timing of decoding of the detection value of the signal of the detection element of interest, SNen, and the detection value of the signal of the detection element of interest, SNen, is output as the transmission difference data.

The control circuit CNT executes first computation to compute first difference data (referred to also as first data) encoded on the basis of the difference between the detection value of the signal of the corresponding detection element on the corresponding line in the previous frame and the detection value of the signal of the detection element of interest in units of one line in the current frame.

Further, the control circuit CNT executes second computation to compute second difference data (referred to also as second data) encoded on the basis of the difference between the average value of the detection values of the signals of the plurality of detection elements included in the reference range RNG as a predetermined range in the current frame and the detection value of the signal of the detection element of interest, SNen, in units of one line in the current frame.

In the case of employing weighted average for calculation of the average value, each detection value is multiplied by a coefficient (weighting factor) when the average value according to the weighted average concerning the detection values of the signals of the detection elements read out previously is calculated in the current frame. At this time, the configuration is made such that the value of the coefficient for the detection element closer to the detection element of interest, SNen, in terms of the distance is larger. As described later, the control circuit CNT executes the first computation and the second computation, and selects one difference data with a smaller data amount (first difference data or second diff data) from the first difference data and the second difference data to output the selected difference data as the transmission difference data. Here, the data amount is the number of bits of the whole of the data to be transmitted (transmission difference data).

Next, the data format DAF of the transmission difference data is described with use of FIG. 7. The data format DAF is a format of difference data corresponding to one line (1HL). The data format DAF has an encoding parameter field ENP and a data field DTF. The encoding parameter field ENP has a first field P01, a second field P02, and a third field P03. The data format DAF includes a basic unit BAU, a first expansion unit EU1, and a second expansion unit EU2.

The encoding parameter field ENP is used for defining encoding parameters of the data format DAF, and is used at the time of decoding of the data format DAF.

The first field PO1 defines whether the first computation using previous frame data has been executed for computation of the difference data or the second computation using the average value in the reference range RNG in the current frame has been executed for computation of the difference data. The first field PO1 is set to, for example, a value of “0” or “1.” For example, “0” defines that the first computation using the previous frame data has been executed for computation of the difference data. “1” defines that the second computation using the average value in the reference range RNG in the current frame has been executed for computation of the difference data. In other words, the data format DAF has the bit (first field P01) indicating whether to refer to data of the detection value of the signal of the detection element in the previous frame or to refer to data of the detection value of the signal of the detection element in the current frame.

The second field PO2 defines the bit length of the basic unit BAU. In representation of the bit length of the basic unit BAU, for example, the bit length is represented by 2 bits as follows: “00” for a bit length of 3 bits; “01” for a bit length of 4 bits; “10” for a bit length of 5 bits; and “11” for a bit length of 6 bits.

The third field P03 defines the bit length of the first expansion unit EU1 and the second expansion unit EU2. In representation of the bit length of the first expansion unit EU1 and the second expansion unit EU2, for example, the bit length is represented by 2 bits as follows: “00” for a bit length of 3 bits; “01” for a bit length of 4 bits; “10” for a bit length of 5 bits; and “11” for a bit length of 6 bits.

The basic unit BAU represents the difference in the detection value of the signal of the detection element of interest, SNen. In FIG. 7, a plurality of basic units BAU each corresponding to a respective one of detection elements SNi1, SNi2, SNi3, SNi4, . . . , SNi1 corresponding to one line (1HL) are set. Each basic unit BAU indicates the difference by, for example, two's complement representation, and a representation range of −2\hat{ } (number of bits−1)+1 to +2\hat{ } (number of bits−1)−2 is represented by each basic unit BAU. When the difference exceeds this representation range, the first expansion unit EU1 and the second expansion unit EU2 are added to represent the difference exceeding this representation range. In other words, when the difference data of the detection element is within predetermined values (for example, representation range of −2\hat{ } (number of bits−1)+1 to +2\hat{ } (number of bits−1)−2), the difference data of the detection element is represented by the basic unit. Moreover, when the difference data of the detection element exceeds the predetermined values, difference data of the predetermined value in the difference data of the detection element is represented by the basic unit, and difference data exceeding the predetermined value in the difference data of the detection element is represented by the expansion unit.

As the basic unit BAU of the detection element SNi1, original data is used when the detection element is the detection element at the upper left.

As many first expansion units EU1 and second expansion units EU2 as required are added when the difference value exceeds the representation range of the basic unit. In this example, a description is given assuming that the number of expansion units (EUx) is two of the first expansion unit EU1 and the second expansion unit EU2. The number of expansion units (EUx) is not limited to two of the first expansion unit EU1 and the second expansion unit EU2, and may be three or four or more. That is, the required number of expansion units to represent the difference value can be added. In the first expansion unit EU1 and the second expansion unit EU2, the first 1 bit is a bit indicating continuation/end, and indicates whether the expansion unit is the last or continues. For example, the first 1 bit indicates the end in a case of “0,” and indicates the continuation in a case of “1.” The remaining bits other than the first 1 bit in the first expansion unit EU1 and the second expansion unit EU2 are bits indicating a numerical value (referred to as numerical bits). The value of the numerical bits represents a value that cannot be completely represented by the basic unit BAU. As many expansion units as required are added on the basis of the result of encoding. The sign of the numerical bit is determined by the basic unit. Even in a case of the negative sign, the first expansion unit EU1 and the second expansion unit EU2 are represented by a positive value.

The basic unit BAU, the first expansion unit EU1, and the second expansion unit EU2 are described below by using case examples.

(Example of Case in Which Basic Unit BAU and Expansion Unit EUx (x=1, 2: EU1, EU2) Have 4 Bits)
1000: difference=−8 or smaller (in this case, basic unit BAU is accompanied by EU1 or EU1 and EU2)
1001: difference=−7 (representation by basic unit BAU is possible)
   to
1111: difference=−1 (representation by basic unit BAU is possible)
0000: difference=0 (representation by basic unit BAU is possible)
0001: difference=+1 (representation by basic unit BAU is possible)
   to
0110: difference=+6 (representation by basic unit BAU is possible)
0111: difference=+7 or larger (in this case, basic unit BAU is accompanied by EU1 or EU1 and EU2)

### (Example of Case in Which First Expansion Unit EU1 and Second Expansion Unit EU2 Each Have 4 Bits)

in a case of difference=−20

A value up to −8 is represented by the basic unit, and thus the remaining 12 (positive value) is represented by the first expansion unit EU1 or the first expansion unit EU1 and the second expansion unit EU2.

The numerical bits included in the expansion unit are 3 bits, and a bit width of 4 bits is required for indicating 12. Thus, two expansion units are used (first expansion unit EU1 and second expansion unit EU2 are used) as described below.
(basic unit BAU): “1000” (−8 or smaller)
(first expansion unit EU1): “1” (continuation) “001”
(second expansion unit EU2): “0” (end) “100”

The numerical bits become 001100=12 through coupling of “001” of the first expansion unit EU1 and “100” of the second expansion unit EU2. This difference of the detection value of the detection element requires 4+4×2=12 bits in total.

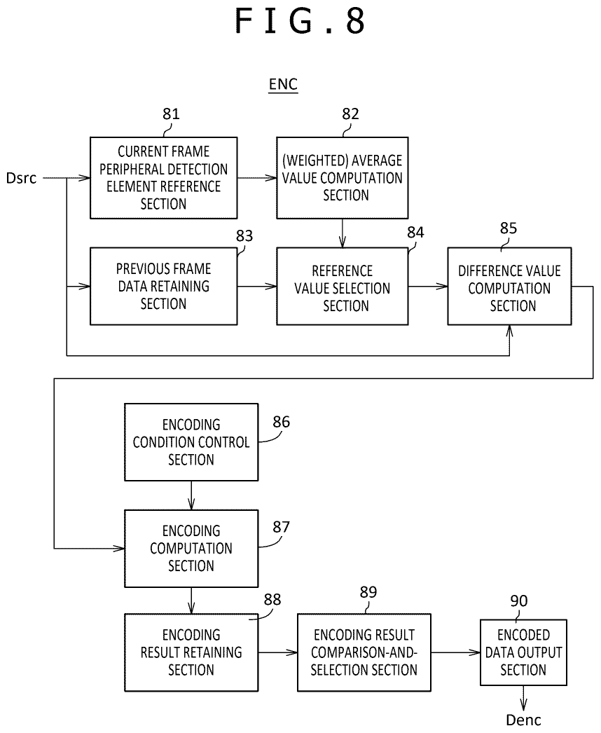

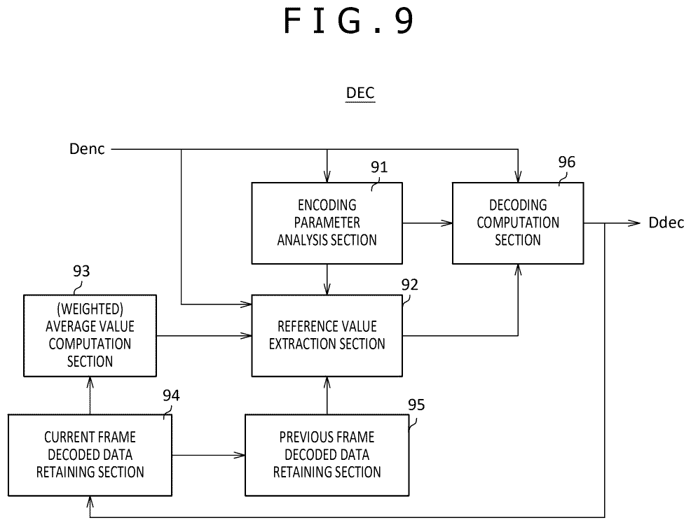

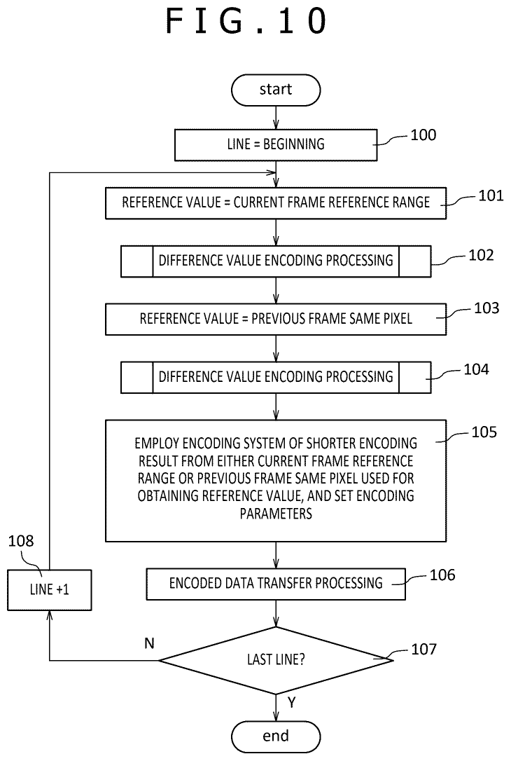

Next, configuration examples of the encoding circuit ENC and the decoding circuit DEC are described with use of FIGS. 8 and 9. FIG. 8 is a block diagram of the encoding circuit according to the embodiment. FIG. 9 is a block diagram of the decoding circuit according to the embodiment.

As depicted in FIG. 8, the encoding circuit ENC includes a current frame peripheral detection element reference section 81, a (weighted) average value computation section 82, a previous frame data retaining section 83, a reference value selection section 84, and a difference value computation section 85. The encoding circuit ENC further includes an encoding condition control section 86, an encoding computation section 87, an encoding result retaining section 88, an encoding result comparison-and-selection section 89, and an encoded data output section 90.

The current frame peripheral detection element reference section 81 is, for example, a reference circuit that includes a line memory of such a number of lines that a reference range in the vertical direction can be included, receives original data Dsrc as the detection value of the signal of the detection element of interest, SNen, and refers to the detection values of the signals of the detection elements in the neighborhood of the detection element of interest, SNen. The detection elements in the neighborhood are the plurality of detection elements in the reference range RNG described with FIG. 3, the detection elements based on the description of FIG. 4, or the plurality of detection elements in the reference range RNG described with FIG. 5.

The (weighted) average value computation section 82 calculates an average value or a weighted average of the detection values of the signals of the plurality of detection elements on the basis of the output of the current frame peripheral detection element reference section 81. When the output of the current frame peripheral detection element reference section 81 corresponds to the plurality of detection elements in the reference range RNG based on FIGS. 3 and 4, the (weighted) average value computation section 82 calculates the average value of the detection values of the signals of the plurality of detection elements in the reference range RNG. Further, when the output of the current frame peripheral detection element reference section 81 corresponds to the plurality of detection elements in the reference range RNG described with FIG. 5, for example, the (weighted) average value computation section 82 calculates the weighted average value of the detection values of the signals of the plurality of detection elements on the basis of the example of the weighted average described above.

The previous frame data retaining section 83 is configured to receive the original data Dsrc, and is configured to be capable of retaining all of the detection values of the signals of the plurality of detection elements in the frame previous to the current frame (previous frame). The previous frame data retaining section 83 has, for example, two frame buffers (for two planes) with a storage capacity for one frame. For example, the detection values (original data Dsrc) of the signals of the plurality of detection elements in the current frame are sequentially written to one of the frame buffers for two planes. When the one of the frame buffers for two planes has become full, next, the detection values (original data Dsrc) of the signals of the plurality of detection elements in the current frame are sequentially written to the other of the frame buffers for two planes. Due to this, all of the detection values of the signals of the plurality of detection elements in the previous frame are retained in the one of the frame buffers for two planes. Moreover, when the other of the frame buffers for two planes has become full, next, the detection values of the signals of the plurality of detection elements in the current frame are sequentially written to the one of the frame buffers for two planes. The configuration is made such that all of the detection values of the signals of the plurality of detection elements in the previous frame can be always retained by repeating the above-described operation.

Further, the previous frame data retaining section 83 has also a function of allowing selection and output of the detection value of the signal of the corresponding detection element in the previous frame according to the original data Dsrc. That is, when the original data Dsrc is the detection value of the signal of the detection element of interest, SNen(im), in FIG. 6, the previous frame data retaining section 83 selects and outputs, as the reference value, the detection value of the signal of the detection element SNim in the previous frame on the basis of the original data Dsrc.

The reference value selection section 84 is configured to be capable of selecting one of the output of the (weighted) average value computation section 82 and the output of the previous frame data retaining section 83.

The difference value computation section 85 computes a difference on the basis of the reference value selected by the reference value selection section 84. In a case in which the reference value selection section 84 has selected, as the reference value, the average value of the detection values of the signals of the plurality of detection elements in the reference range RNG described with FIG. 3 or the detection elements based on the description of FIG. 4, the difference value computation section 85 computes the difference between the average value of the detection values of the signals of the plurality of detection elements and the original data Dsrc as the detection value of the signal of the detection element of interest, SNen. In a case in which the reference value selection section 84 has selected, as the reference value, the weighted average value of the detection values of the signals of the plurality of detection elements in the reference range RNG described with FIG. 5, the difference value computation section 85 computes the difference between the weighted average value of the detection values of the signals of the plurality of detection elements and the original data Dsrc as the detection value of the signal of the detection element of interest, SNen. In a case in which the reference value selection section 84 has selected the detection value of the signal of the corresponding detection element in the previous frame as the reference value, the difference value computation section 85 computes the difference between the detection value of the signal of the corresponding detection element in the previous frame and the original data Dsrc as the detection value of the signal of the detection element of interest, SNen.

The encoding condition control section 86 controls a test encoding condition for changing the numbers of bits of the basic unit BAU and the expansion units EU1 and EU2 to various numbers of bits and executing test encoding for each one line. This can find a combination that gives the shortest data length of the data format DAF of the transmission difference data. For example, when the bit length definition is set with 3 bits to 6 bits, test encoding is executed with 4×4=16 combinations obtained by setting each bit length of the basic unit BAU and the expansion units EU1 and EU2 to 3 bits to 6 bits in a round-robin manner. Then, the combination with which the total bit length of the data format DAF becomes the shortest is employed.

The encoding computation section 87 executes encoding of the difference received from the difference value computation section 85 on the basis of the test encoding condition received from the encoding condition control section 86. The encoding condition control section 86 sequentially supplies, to the encoding computation section 87, the test encoding condition for changing the numbers of bits of the basic unit BAU and the expansion units EU1 and EU2 to various numbers of bits for each one line, and the encoding computation section 87 executes the encoding of the difference on the basis of each test encoding condition. In other words, the encoding computation section 87 executes, as the test encoding, test encoding computation including the first computation to compute the first difference data encoded on the basis of the difference between the detection value of the signal of the corresponding detection element on the corresponding line in the previous frame and the detection value of the signal of the detection element of interest, in units of one line in the current frame, and the second computation to compute the second difference data encoded on the basis of the difference from the average value of the detection values of the signals of the detection elements included in the predetermined range in the current frame. In these first computation and second computation, on the basis of the test encoding condition, the encoding computation section 87 changes the numbers of bits of the basic unit BAU and the expansion units EU1 and EU2 to various numbers of bits and executes the test encoding for each one line. Here, as each piece of encoded data, the data format DAF having the encoding parameter field ENP and the data field DTF like that depicted in FIG. 7 may be employed.

The encoding result retaining section 88 stores an encoding result of the basic unit BAU and the expansion units EU1 and EU2 in units of one line, encoded on the basis of each test encoding condition.

The encoding result comparison-and-selection section 89 selects one piece of encoded data with the shortest total bit length of the data format DAF from a plurality of pieces of encoded data that are stored in the encoding result retaining section 88 and relate to the same line, and transmits the selected encoded data to the encoded data output section 90.

The encoded data output section 90 receives the encoded data selected by the encoding result comparison-and-selection section 89, and outputs the received encoded data as encoded data Denc. This encoded data Denc is transmitted to the transmitting circuit TX in FIG. 1 as the transmission difference data, and, for example, is transmitted from the transmitting antenna AN1 as a wireless signal and is received by the receiving antenna AN2 of the host apparatus HST.

As depicted in FIG. 9, the decoding circuit DEC includes an encoding parameter analysis section 91, a reference value extraction section 92, a previous frame decoded data retaining section 95, a (weighted) average value computation section 93, a current frame decoded data retaining section 94, and a decoding computation section 96.

The wireless signal received by the receiving antenna AN2 is converted to the encoded data Denc by the receiving circuit RX, and is supplied to the encoding parameter analysis section 91 as received difference data. As a format of the received difference data, for example, the data format DAF having the encoding parameter field ENP and the data field DTF in FIG. 7 is employed. The encoding parameter analysis section 91 executes analysis of the encoding parameter field ENP of the supplied encoded data Denc. The encoding parameter field ENP has the first field P01, the second field P02, and the third field P03 as described with FIG. 7. Through analysis of the first field P01, it is known whether the first computation using previous frame data has been executed for computation of the difference data or the second computation using the average value in the reference range RNG in the current frame has been executed for computation of the difference data. The bit length of the basic unit BAU is known through analysis of the second field P02. Further, the bit length of the first expansion unit EU1 and the second expansion unit EU2 is known through analysis of the third field P03.

The reference value extraction section 92 receives the encoded data Denc and the analysis result of the encoding parameter field ENP, and executes computation of extracting the reference value used in the generation of the encoded data Denc. Moreover, the reference value extraction section 92 is configured to receive also an output value output from the (weighted) average value computation section 93, an output value output from the previous frame decoded data retaining section 95, and the like.

The decoding computation section 96 outputs decoded data Ddec obtained by executing decoding computation for the encoded data Denc on the basis of the analysis result of the encoding parameter field ENP and the reference value output from the reference value extraction section 92. Further, the decoded data Ddec is supplied to the current frame decoded data retaining section 94 and is stored therein.

For example, in a case in which the encoded data Denc includes a detection value DSNen00 of the first detection element SNen00 at the left end on the first line of the sensor array SARY, data of the detection value DSNen00 itself is represented by the first basic unit BAU or the basic unit BAU, the first expansion unit EU1, and the second expansion unit EU2 in the encoded data Denc. Thus, the reference value extraction section 92 extracts the detection value DSNen00 and outputs it to the decoding computation section 96, and the decoding computation section 96 outputs the detection value DSNen00 as the decoded data Ddec. In addition, the detection value DSNen00 is supplied to the current frame decoded data retaining section 94 and is stored therein.

Next, in a case in which the encoded data Denc includes encoded data of a detection value DSNen001 of a second detection element SNen001 on the right side of the first detection element SNen00 at the left end on the first line of the sensor array SARY, the encoded data of the detection value DSNen001 is the difference between the reference value and the detection value DSNen001 of the detection element SNen001 on the right side, with the detection value DSNen00 being the reference value. Thus, the detection value DSNen00 output from the current frame decoded data retaining section 94 passes through the (weighted) average value computation section 93 and is extracted by the reference value extraction section 92, and is then supplied from the reference value extraction section 92 to the decoding computation section 96. The decoding computation section 96 adds the difference to the detection value DSNen00 to calculate the detection value DSNen001 as the decoded data Ddec. Further, the detection value DSNen001 is supplied to the current frame decoded data retaining section 94 and is stored therein.

Next, in a case in which the encoded data Denc includes encoded data of a detection value DSNen002 of a third detection element SNen002 on the right side of the detection element SNen001 on the first line of the sensor array SARY, the encoded data of the detection value DSNen002 is the difference between the reference value and the detection value DSNen002 of the detection element SNen002, with the average value of the detection value DSNen00 and the detection value DSNen001 being the reference value. Thus, the detection value DSNen00 and the detection value DSNen001 output from the current frame decoded data retaining section 94 are supplied to the (weighted) average value computation section 93, and an average value is calculated. Then, the calculated average value is extracted by the reference value extraction section 92, and is supplied from the reference value extraction section 92 to the decoding computation section 96. The decoding computation section 96 adds the difference to the average value to calculate the detection value DSNen002 as the decoded data Ddec. Moreover, the detection value DSNen002 is supplied to the current frame decoded data retaining section 94 and is stored therein.

Such decoding computation is sequentially executed for the data format DAF of each line. Thereby, the detection values concerning the detection elements on all lines of the sensor array SARY relating to the current frame are obtained. The above-described decoding computation relates to decoding computation concerning the encoding method described with FIGS. 3 and 4. In a case of the encoding method using the weighted average described with FIG. 5, a weighted average is computed by the (weighted) average value computation section 93 and is extracted by the reference value extraction section 92.

In a case of the encoding method using data of the detection value in the previous frame as the reference value, described with FIG. 6, the previous frame decoded data retaining section 95 and the current frame decoded data retaining section 94 in FIG. 9 are used. When the current frame decoded data retaining section 94 as a first frame has become full, all detection values of the current frame are, for example, transferred to the previous frame decoded data retaining section 95 and are retained therein, and the retained data in the current frame decoded data retaining section 94 is deleted and the current frame decoded data retaining section 94 is made empty. Then, in a case in which the data format DAF includes the difference of the first detection element SNen00 at the left end on the first line of the sensor array SARY relating to the current frame as a second frame, the detection value of the first detection element at the left end on the first line of the sensor array SARY, retained in the previous frame decoded data retaining section 95, is extracted by the reference value extraction section 92 as the reference value, and is supplied from the reference value extraction section 92 to the decoding computation section 96. This allows the decoding computation section 96 to add the detection value of the corresponding detection element in the previous frame to the difference of the first detection element SNen00 at the left end on the first line of the sensor array SARY relating to the current frame to execute decoding computation of the detection value of the detection element SNen00. Then, the detection value of the detection element SNen00 is retained in the current frame decoded data retaining section 94 as the decoded data Ddec. By sequentially executing such computation, the data format DAF relating to the encoding method described with FIG. 6 can be decoded.

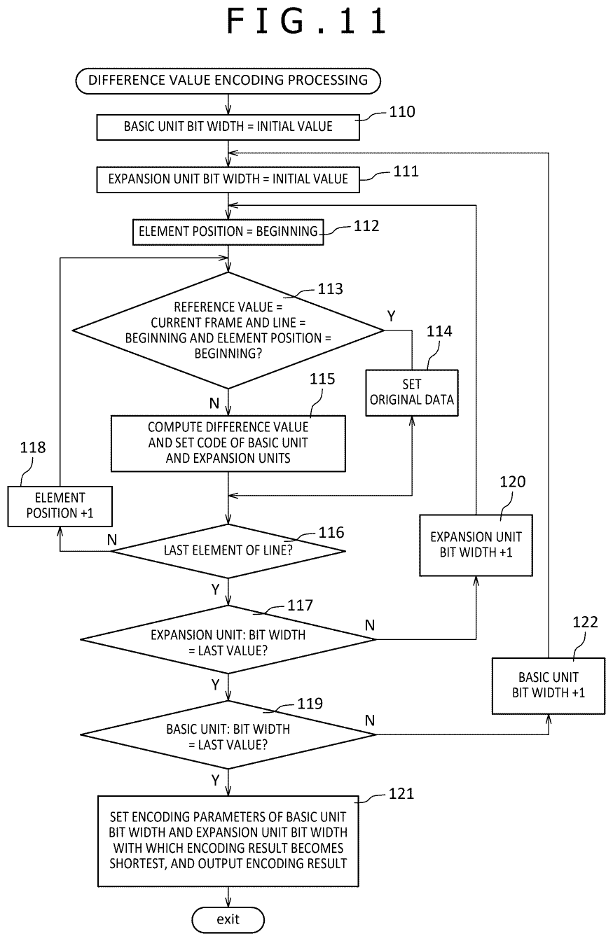

Next, an encoding procedure and difference value encoding processing are described with use of FIGS. 10 and 11. FIG. 10 is a flowchart for explaining the encoding procedure according to the embodiment. FIG. 11 is a flowchart for explaining the difference value encoding processing in FIG. 10.

As depicted in FIG. 10, the encoding procedure has steps 100 to 108. Each step is described below. It is assumed that these steps 100 to 108 are executed by the control circuit CNT in FIG. 1.

### (Step 100)

In order to set the first encoding position, a line variable is set to the beginning line that is the first line of the sensor array SARY.

### (Step 101)

The reference value required for encoding is set to an average value of the detection values of detection pixels in the reference range RNG in the current frame (see FIGS. 3 and 4).

### (Step 102: Difference Value Encoding Processing)

On the basis of the setting of the reference value in the step 101, the second computation that is encoding processing using the value of the difference between the detection value of the detection element of interest and the average value of the detection values of the detection pixels in the reference range RNG is executed (see FIGS. 3 and 4). This encoding processing is executed concerning, for example, the detection elements on one line. At this time, as described with FIG. 11, encoding processing in which the numbers of bits of the basic unit BAU and the expansion units EU1 and EU2 are changed to various numbers of bits is executed.

### (Step 103)

Next, the detection element from which the reference value required for encoding is obtained is set to the detection element in the previous frame at the same position (for example, m-th position from the left side on the n-th line in the previous frame) as the position of the detection element of interest in the current frame (m-th position from the left side on the n-th line in the current frame) (see FIG. 6).

### (Step 104: Difference Value Encoding Processing)

On the basis of the setting of the reference value in the step 103, the first computation that is encoding processing using the value of the difference between the detection value of the detection element of interest in the current frame and the detection value of the detection element in the previous frame is executed (see FIG. 6). This encoding processing is executed concerning, for example, the detection elements on one line in the current frame. At this time, as described with FIG. 11, encoding processing in which the numbers of bits of the basic unit BAU and the expansion units EU1 and EU2 are changed to various numbers of bits is also executed.

### (Step 105)

The number of bits of the data field DTF of encoded data obtained in the step 102 (encoding result of the second computation) is compared with the number of bits of the data field DTF of encoded data obtained in the step 104 (encoding result of the first computation), and the encoding system of the smaller number of bits is employed.

This can set the encoding parameter field ENP.

### (Step 106)

Transfer processing of integrating the encoding parameter field ENP decided in the step 105 and the data field DTF to make the transmission difference data, and transferring the encoded data to the side of the host apparatus HST is executed. This transfer is executed as transmission by using, for example, a transmission system involving band limitation, such as wireless communication.

### (Step 107)

Next, it is determined whether or not the line variable is the last line of the sensor array SARY. When the line variable is the last line (Y), the encoding processing ends. When the line variable is not the last line (N), the processing is moved to a step 108.

### (Step 108)

The value of the line variable is incremented by +1, and the processing is moved to the step 101. Due to this, encoding processing for the next line is started in the step 101.

The difference value encoding processing of the steps 102 and 104 is described with use of FIG. 11. The difference value encoding processing has steps 110 to 122. Each step is described below. It is assumed that these steps 110 to 122 are executed by the control circuit CNT in FIG. 1. In this processing, as described above, for example, when the bit length definition is set with 3 bits to 6 bits, test encoding as the difference value encoding processing is executed with 4×4=16 combinations obtained by setting each bit length of the basic unit BAU and the expansion units EU1 and EU2 to 3 bits to 6 bits in a round-robin manner. This allows discrimination of the combination of the bit lengths of the basic unit BAU and the expansion units EU1 and EU2 with which the total bit length of the data format DAF (data field DTF) becomes the shortest. This processing is executed by changing, by the encoding condition control section 86, the numbers of bits of the basic unit BAU and the expansion units EU1 and EU2 to various numbers of bits for each one line.

### (Step 110)

First, the bit width of the basic unit BAU is set to an initial value. For example, when the bit length definition is set with 3 bits to 6 bits, the initial value of the bit width can be set to 3 bits.

### (Step 111)

Next, the bit width of the expansion units EU1 and EU2 is set to an initial value. For example, when the bit length definition is set with 3 bits to 6 bits, the initial value of the bit width can be set to 3 bits.

### (Step 112)

Next, the position of the detection element of interest is set to the beginning position at the left end on the beginning line that is the first line of the sensor array SARY.

(Step 113) Next, the following determinations are executed.
1) Is the reference value based on the detection value of the detection element in the current frame?
2) Is the position of the line of the detection element of interest is the beginning line position?
3) Is the position of the detection element of interest is the position at the beginning of the line?

When all of the above-described 1) to 3) are met (Y), the processing is moved to a step 114. When not all of the above-described 1) to 3) are met (N), the processing is moved to a step 115.

### (Step 114)

The reference value is set to original data.

### (Step 115)

The difference (difference value) of the detection value of the detection element of interest is computed on the basis of the reference value. Then, on the basis of the computed difference, data (code) of the basic unit BAU and the expansion units EU1 and EU2 is set.

### (Step 116)

Next, whether or not the position of the detection element of interest is the position of the last detection element of the line is determined. When the position of the detection element of interest is the position of the last detection element of the line (Y), the processing is moved to a step 117. When the position of the detection element of interest is not the position of the last detection element of the line (N), the processing is moved to a step 118.

### (Step 117)

Whether or not the bit width of the expansion units EU1 and EU2 is the last value is determined. For example, when the bit length definition is set with 3 bits to 6 bits, whether or not the bit width is 6 bits is determined. When the bit width is the last value (Y), the processing is moved to a step 119. When the bit width is not the last value (N), the processing is moved to a step 120.

### (Step 118)

The position of the detection element of interest is incremented by +1, and the processing is moved to the step 113.

### (Step 119)

Whether or not the bit width of the basic unit BAU is the last value is determined. For example, when the bit length definition is set with 3 bits to 6 bits, whether or not the bit width is 6 bits is determined. When the bit width is the last value (Y), the processing is moved to a step 121. When the bit width is not the last value (N), the processing is moved to a step 122.

### (Step 120)

The bit width of the expansion units EU1 and EU2 is incremented by +1, and the processing is moved to the step 112.

### (Step 121)

In the data field DTF of the encoding result, the combination of the bit width of the basic unit BAU and the bit width of the expansion units EU1 and EU2, with which the number of bits of the data field DTF becomes the smallest, is sought. Then, the encoding parameters relating to the first field P01, the second field P02, and the third field P03 of the encoding parameter field ENP are set on the basis of the combination of the bit width of the basic unit BAU and the bit width of the expansion units EU1 and EU2, with which the number of bits becomes the smallest, and the data format DAF of the transmission difference data including the set encoding parameter field ENP and the data field DTF is output as the encoding result.

### (Step 122)

The bit width of the basic unit BAU is incremented by +1, and the processing is moved to the step 111.

According to the above embodiment, the following one or multiple effects can be obtained.

1) The difference value between the reference value and the detection value of the signal of the detection element of interest, SNen, is recorded and transmitted as the data format. Due to this, a digital value with a smaller number of bits than the normal absolute value (digital data with the number of bits resulting from representing the detection value of the signal as it is) is obtained. Thus, an effect that the amount of data sent in a unit time is reduced can be obtained.

2) In the data format DAF, the number of bits of the basic unit BAU and the number of bits of the expansion units EU1 and EU2 for a value relating to the detection value of the detection element, with which the data length becomes the minimum are set for each one line. Thus, the compression ratio of the data format DAF improves.

3) Due to the above-described 2), the amount of data sent in a unit time can be reduced in the case of transmitting the sensor data by using a transmission system involving band limitation.

### (Modification)

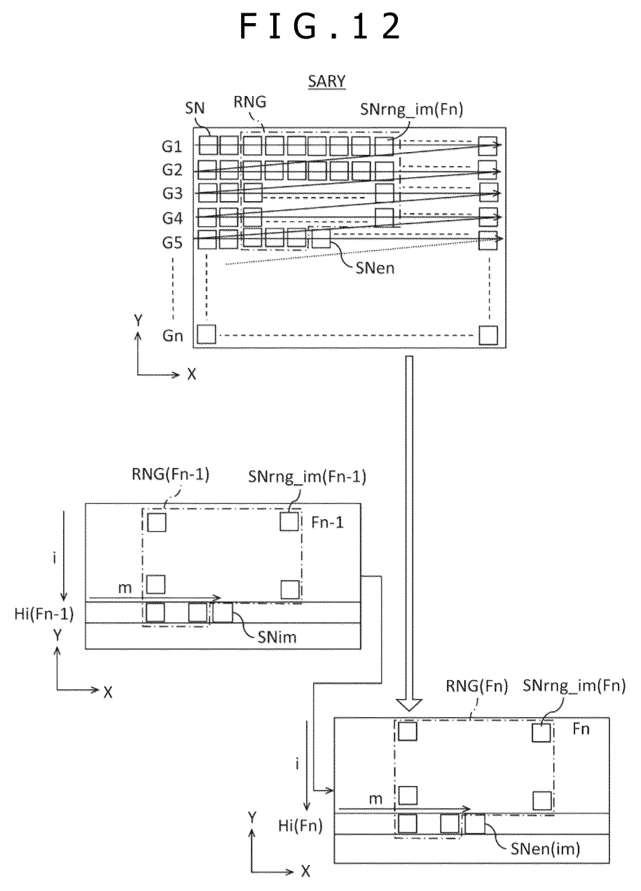

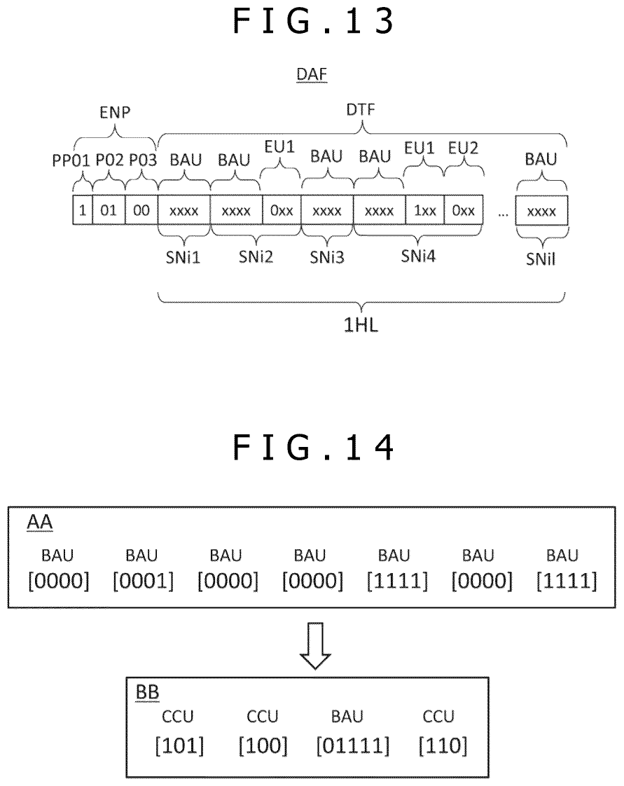

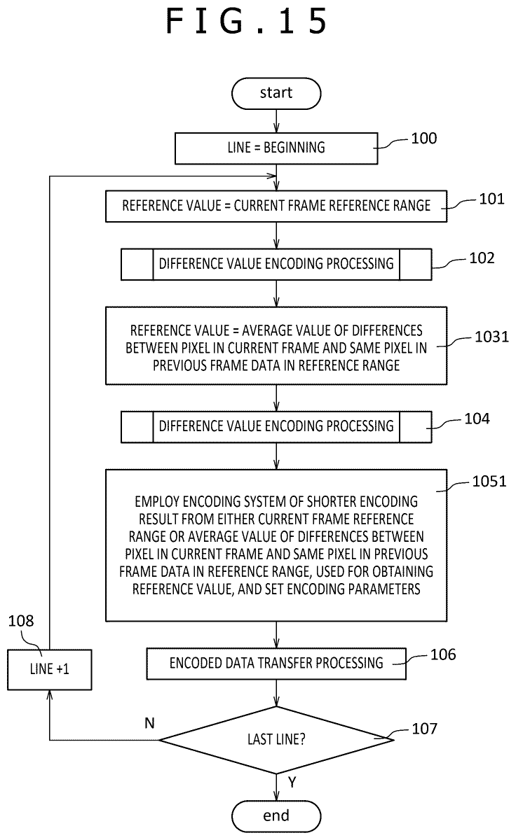

A modification is described with use of FIGS. 12 to 15. FIG. 12 is a diagram for explaining a fifth example of the encoding method according to the modification. FIG. 13 is a diagram for explaining a data format according to the modification. FIG. 14 is a diagram for explaining a configuration example of a consecutiveness compression unit according to the modification. FIG. 15 is a flowchart for explaining an encoding procedure according to the modification.

First, the fifth example of the encoding method is described with use of FIG. 12. The fifth example of the encoding method in FIG. 12 is a modification of the fourth example of the encoding method in FIG. 6. In the fourth example of the encoding method, “the detection value of the signal of the detection element of interest, SNen, in the current frame Fn and the detection value of the signal of the detection element SNim disposed at the same position as the detection element of interest, SNen(im), in the previous frame Fn-1” are employed for “the reference value of difference computation.”

On the other hand, in the fifth example of the encoding method in FIG. 12, “the detection value of the signal of the detection element of interest, SNen, in the current frame Fn and an average value of the differences in the detection value (detection data) of the same pixel between the current frame Fn and the previous frame Fn-1 in the predetermined range (reference range) RNG previous to the detection element of interest, SNen, in the current frame Fn” are employed for “the reference value of difference computation.”

Here, it can be said that the average value of the differences in the detection value of the same pixel between the current frame Fn and the previous frame Fn-1 in the predetermined range RNG previous to the detection element of interest, SNen, in the current frame En is a value based on the detection value of the signal of the detection element read out before the detection timing of the detection value of the signal of the detection element of interest.

A description is given of the average value of the differences in the detection value of the same pixel between the current frame Fn and the previous frame Fn-1 in the predetermined range RNG previous to the detection element of interest, SNen, in the current frame Fn.

In FIG. 12, the detection element of interest, SNen, is the detection element of interest, SNen(im), in the current frame Fn. The predetermined range RNG previous to the detection element of interest, SNen, in the current frame Fn is a predetermined range RNG(Fn) in the current frame Fn, and the predetermined range RNG in the previous frame Fn-1 is a predetermined range RNG(Fn-1). The detection value of the same pixel in the current frame Fn and the previous frame Fn-1 in the predetermined range RNG indicates the detection value of a detection element SNrng_im(Fn) in the predetermined range RNG(Fn) in the current frame Fn and the detection value of a detection element SNrng_im(Fn-1) in the predetermined range RNG(Fn-1) in the previous frame Fn-1. Here, the same pixel in the current frame Fn and the previous frame Fn-1 means that im is set to the same value in the detection element SNrng_im(Fn) and the detection element SNrng_im(Fn-1). Here, im used in SNrng_im(Fn) and SNrng_im(Fn-1) is the disposition number (number of row and column) of the plurality of detection elements disposed in the predetermined range RNG(Fn, Fn-1).

The difference in the detection value of the same pixel between the current frame Fn and the previous frame Fn-1 is the difference between the detection value of the detection element SNrng im(Fn) and the detection value of the detection element SNrng im(Fn-1) (im is the number of the same disposition in the plurality of detection elements in the predetermined range RNG(Fn, Fn-1)).

The average value of the differences in the detection value of the same pixel between the current frame Fn and the previous frame Fn-1 is described. Here, the description is schematically given assuming that im used in SNrng_im(Fn) and SNrng_im(Fn-1) is 1 to 10. Further, the difference between the detection value of SNrng im(Fn) and the detection value of SNrng im(Fn-1) is represented as difference (im) (im is 1 to 10).

In this case, an average value Dave of the differences in the detection value of the same pixel between the current frame Fn and the previous frame Fn-1 is represented by the following formula.

$$Dave = ( ( difference ( 1 ) + difference ( 2 ) + ... + difference ( 9 ) + difference ( 10 ) ) / 10$$

Therefore, the difference computation is computation of the difference between the detection value of the signal of the detection element of interest, SNen, in the current frame Fn and the average value Dave.

That is, the detection circuit DETA includes the plurality of detection elements SN arranged in a matrix form, the plurality of scanning lines G that extend in the first direction X and are arranged in the second direction Y intersecting the first direction X, and are connected to the scan circuit SC, the plurality of signal lines S that extend in the second direction Y and are arranged in the first direction X, and are connected to the detection circuit DET, and the control circuit CNT. Each of the plurality of detection elements SN is connected to the corresponding scanning line (Gn, Gn+1) and the corresponding signal line (Sn, Sn+1). The detection circuit DET is configured to sequentially read out the detection values of the signals of the plurality of detection elements SN through the plurality of signal lines S. When the detection value of the signal of the detection element of interest, SNen, is externally output, the control circuit CNT outputs, as the transmission difference data, the difference data between the value based on the detection value of the signal of the detection element read out before the detection timing of the detection value of the signal of the detection element of interest, SNen, and the detection value of the signal of the detection element of interest, SNen. Here, as the value based on the detection value of the signal of the detection element read out before the detection timing of the detection value of the signal of the detection element of interest, SNen, the average value of the differences in the detection value of the same pixel between the current frame Fn and the previous frame Fn-1 in the predetermined range RNG previous to the detection element of interest, SNen, in the current frame Fn is employed.

The transmission difference data is difference data obtained by collecting, in units of one line in the current frame, a plurality of differences when each of a plurality of detection elements included in the corresponding line is employed as the detection element of interest, SNen. When X lines exist in the current frame, the transmission difference data includes X pieces of difference data corresponding to the X lines. The detection timing of the detection value of the signal of the detection element of interest, SNen, may be rephrased into the timing of decoding of the detection value of the signal of the detection element of interest, SNen. That is, the difference data between the value based on the detection value of the signal of the detection element read out before the timing of decoding of the detection value of the signal of the detection element of interest, SNen, and the detection value of the signal of the detection element of interest, SNen, is output as the transmission difference data.

Next, the data format DAF of the transmission difference data is described with use of FIG. 13. The data format DAF is a format of difference data corresponding to one line (1HL). The data format DAF has the encoding parameter field ENP and the data field DTF. The encoding parameter field ENP has a first field PP01, the second field P02, and the third field P03. The data format DAF includes the basic unit BAU, the first expansion unit EU1, and the second expansion unit EU2.

As described with FIG. 14, the consecutiveness compression unit may be set in the data format DAF of the transmission difference data. In this case, the data format DAF is provided with the basic unit BAU, the first expansion unit EU1, the second expansion unit EU2, and a consecutiveness compression unit CCU.

The encoding parameter field ENP is used for defining encoding parameters of the data format DAF, and is used at the time of decoding of the data format DAF.

The first field PP01 defines whether computation using the average value of the differences in the detection value (detection data) of the same pixel between the current frame Fn and the previous frame Fn-1 in the predetermined range (reference range) RNG previous to the detection element of interest, SNen, in the current frame Fn has been executed for computation of the difference data or the second computation using the average value in the reference range RNG in the current frame has been executed for computation of the difference data. The first field PP01 is set to, for example, a value of “0” or “1.” For example, “0” defines that the second computation using the average value in the reference range RNG in the current frame has been executed for computation of the difference data. “1” defines that the computation using the average value of the differences in the detection value (detection data) of the same pixel between the current frame Fn and the previous frame Fn-1 in the predetermined range (reference range) RNG previous to the detection element of interest, SNen, in the current frame Fn has been executed. In other words, the difference data of one line further has, at the beginning, the bit (first field PP01) indicating whether the average value of the differences in the same pixel data between the current frame and the previous frame in the predetermined range previous to the detection element of interest in the current frame is employed or the average value in the reference range in the current frame is employed.

The second field P02 defines the bit length of the basic unit BAU. In representation of the bit length of the basic unit BAU, for example, the bit length is represented by 2 bits as follows: “00” for a bit length of 3 bits; “01” for a bit length of 4 bits; “10” for a bit length of 5 bits; and “11” for a bit length of 6 bits.

The third field P03 defines the bit length of the first expansion unit EU1 and the second expansion unit EU2. In representation of the bit length of the first expansion unit EU1 and the second expansion unit EU2, for example, the bit length is represented by 2 bits as follows: “00” for a bit length of 3 bits; “01” for a bit length of 4 bits; “10” for a bit length of 5 bits; and “11” for a bit length of 6 bits.

The basic unit BAU represents the difference in the detection value of the signal of the detection element of interest, SNen. In FIG. 13, a plurality of basic units BAU each corresponding to a respective one of the detection elements SNi1, SNi2, SNi3, SNi4, . . . , SNi1 corresponding to one line (1HL) are set. Each basic unit BAU indicates the difference by, for example, two's complement representation, and a representation range of −2\hat{ } (number of bits−1)+1 to +2\hat{ } (number of bits−1)−2 is represented by each basic unit BAU. When the difference exceeds this representation range, the first expansion unit EU1 and the second expansion unit EU2 are added to represent the difference exceeding this representation range. In other words, when the difference data of the detection element is within predetermined values (for example, representation range of −2\hat{ } (number of bits−1)+1 to +2\hat{ } (number of bits 1)−2), the difference data of the detection element is represented by the basic unit. Moreover, when the difference data of the detection element exceeds the predetermined values, difference data of the predetermined value in the difference data of the detection element is represented by the basic unit, and difference data exceeding the predetermined value in the difference data of the detection element is represented by the expansion unit.

As the basic unit BAU of the detection element SNi1, original data is used when the detection element is the detection element at the upper left.

As many first expansion units EU1 and second expansion units EU2 as required are added when the difference value exceeds the representation range of the basic unit. In this example, a description is given assuming that the number of expansion units (EUx) is two, the first expansion unit EU1 and the second expansion unit EU2. The number of expansion units (EUx) is not limited to two of the first expansion unit EU1 and the second expansion unit EU2, and may be three or four or more. That is, the required number of expansion units to represent the difference value can be added. In the first expansion unit EU1 and the second expansion unit EU2, the first 1 bit is a bit indicating continuation/end, and indicates whether the expansion unit is the last or continues. For example, the first 1 bit indicates the end in a case of “0,” and indicates the continuation in a case of “1.” The remaining bits other than the first 1 bit in the first expansion unit EU1 and the second expansion unit EU2 are bits indicating a numerical value (referred to as numerical bits). The value of the numerical bits represents a value that cannot be completely represented by the basic unit BAU. As many expansion units as required are added on the basis of the result of encoding. The sign of the numerical bit is determined by the basic unit. Even in a case of the negative sign, the first expansion unit EU1 and the second expansion unit EU2 are represented by a positive value.

The basic unit BAU, the first expansion unit EU1, and the second expansion unit EU2 are described below by using case examples.

(Example of Case in Which Basic Unit BAU and Expansion Unit EUx (x=1, 2: EU1, EU2) Have 4 Bits)
1000: difference=−8 or smaller (in this case, basic unit BAU is accompanied by EU1 or EU1 and EU2)
1001: difference=−7 (representation by basic unit BAU is possible)
   to
1111: difference=−1 (representation by basic unit BAU is possible)
0000: difference=0 (representation by basic unit BAU is possible)
0001: difference=+1 (representation by basic unit BAU is possible)
   to
0110: difference=+6 (representation by basic unit BAU is possible)
0111: difference=+7 or larger (in this case, basic unit BAU is accompanied by EU1 or EU1 and EU2)

### (Example of Case in Which First Expansion Unit EU1 and Second Expansion Unit EU2 Each Have 4 Bits)

in a case of difference=−20

A value up to −8 is represented by the basic unit, and thus the remaining 12 (positive value) is represented by the first expansion unit EU1 or the first expansion unit EU1 and the second expansion unit EU2.

The numerical bits included in the expansion unit are 3 bits, and a bit width of 4 bits is required for indicating 12. Thus, two expansion units are used (first expansion unit EU1 and second expansion unit EU2 are used) as described below.
(basic unit BAU): “01000” (−8 or smaller)
(first expansion unit EU1): “1” (continuation) “001”
(second expansion unit EU2): “0” (end) “100”

The first “0” in the basic unit BAU “01000” indicates that the unit is the basic unit BAU.

The numerical bits become 001100=12 through coupling of “001” of the first expansion unit EU1 and “100” of the second expansion unit EU2. This difference of the detection value of the detection element requires 5+4×2=13 bits in total.

### (Configuration Example of Consecutiveness Compression Unit)

The consecutiveness compression unit CCU can be used when the basic units BAU corresponding with a condition that is set on the assumption that the condition frequently occurs at the time of encoding are consecutive. The consecutiveness compression unit CCU can be configured by 3 bits as follows. The consecutiveness compression unit CCU may be configured with the number of bits other than 3 bits.
100: when difference 0 and difference 0 are consecutive
101: when difference 0 and difference +1 are consecutive
110: when difference 0 and difference −1 are consecutive
111: when difference+1 and difference 0 are consecutive

Here, “1” of the first 1 bit indicates that the unit is the consecutiveness compression unit.

For example, as depicted in FIG. 14, transmission difference data AA in which original data is composed of seven basic units BAU (total of 28 bits) can be turned to transmission difference data BB with a total of 14 bits by using three consecutiveness compression units CCU (9 bits) and one basic unit BAU (5 bits). The first “0” in the basic unit BAU “01111” indicates that the unit is the basic unit BAU. In other words, the configuration can be made such that, when a predetermined number of predetermined basic units BAU are consecutive, these consecutive basic units BAU are replaced by the consecutiveness compression unit CCU with a predetermined number of bits.

Next, the encoding procedure according to the modification is described with use of FIG. 15. Different points of the flowchart of FIG. 15 from the flowchart of FIG. 10 are as follows. First, the step 103 in the flowchart of FIG. 10 is turned to a step 1031 with a change to “reference value=average value of differences between pixel in current frame and same pixel in previous frame data in reference range.” Second, the step 105 in the flowchart of FIG. 10 is turned to a step 1051 with a change to “employ encoding system of shorter encoding result from either current frame reference range or average value of differences between pixel in current frame and same pixel in previous frame data in reference range, used for obtaining reference value, and set encoding parameters.”

The steps 100 to 102, 104, and 106 to 108 other than the steps 1031 and 1051 in the flowchart of FIG. 15 are the same as the steps 100 to 102, 104, and 106 to 108 in FIG. 10. Thus, overlapping description concerning the steps 100 to 102, 104, and 106 to 108 is omitted. Further, as with the steps 102 and 104 in FIG. 10, the difference value encoding processing of FIG. 11 is used for the steps 102 and 104 in FIG. 15.

As depicted in FIG. 15, the steps 100 to 102 are executed. Here, a description is given from the step 102.

### (Step 102: Difference Value Encoding Processing)

On the basis of the setting of the reference value in the step 101, the second computation that is encoding processing using the value of the difference between the detection value of the detection element of interest and the average value of the detection values of the detection pixels in the reference range RNG is executed (see FIGS. 3 and 4). This encoding processing is executed concerning, for example, the detection elements on one line. At this time, as described with FIG. 13, encoding processing in which the numbers of bits of the basic unit BAU and the expansion units EU1 and EU2 are changed to various numbers of bits is executed. Thereafter, the processing is moved to the step 1031.

### (Step 1031)

The step 1031 is executed after the step 102. In the step 1031, the detection element for obtaining the reference value required for encoding is set to the detection element of interest, SNen, in the current frame Fn, and the reference value is set to the average value of the differences in the detection value (detection data) of the same pixel between the current frame Fn and the previous frame Fn-1 in the predetermined range (reference range) RNG previous to the detection element of interest, SNen, in the current frame Fn (see FIG. 12).

### (Step 104: Difference Value Encoding Processing)

On the basis of the setting of the reference value in the step 1031, computation that is encoding processing using the average value of the differences in the detection value (detection data) of the same pixel between the current frame Fn and the previous frame Fn-1 in the predetermined range (reference range) RNG previous to the detection element of interest, SNen, in the current frame Fn is executed. This encoding processing is executed concerning, for example, the detection elements on one line. At this time, as described with FIG. 13, encoding processing in which the numbers of bits of the basic unit BAU and the expansion units EU1 and EU2 are changed to various numbers of bits is executed. Thereafter, the processing is moved to the step 1051.

### (Step 1051)

The number of bits of the data field DTF of encoded data obtained in the step 102 is compared with the number of bits of the data field DTF of encoded data obtained in the step 104, and the encoding system of the smaller number of bits is employed. This can set the encoding parameter field ENP.

The steps 106 to 108 are executed after the step 1051.

In the above-described steps 102 and 104 in FIG. 15, that is, in the difference value encoding processing in FIG. 11, determination of whether to apply the consecutiveness compression unit described with FIG. 14 and encoding processing in a case in which the consecutiveness compression unit is applied may be additionally executed.

For example, after the encoding parameters relating to the first field PP01, the second field P02, and the third field P03 of the encoding parameter field ENP are set in the step 121 on the basis of the combination of the bit width of the basic unit BAU and the bit width of the expansion units EU1 and EU2, with which the data field DTF becomes the shortest, the number of bits in the case in which the consecutiveness compression unit CCU is applied is calculated in consideration of the consecutiveness of the basic unit BAU. Then, when it is determined that the number of bits of the data field DTF can be reduced to a predetermined value or smaller by the application of the consecutiveness compression unit CCU, the first field PP01 is changed to the application of the consecutiveness compression unit CCU, and a part of a plurality of consecutive basic units BAU in the data field DTF is replaced by the consecutiveness compression unit CCU to reconstruct the data field DTF. Further, the configuration is made such that the data format DAF of the transmission difference data including the set encoding parameter field ENP and the data field DTF is output as the encoding result.

The above modification can also achieve effects equivalent to those of the embodiment. Moreover, because the consecutiveness compression unit CCU is employed for the data format DAF, the compression ratio of the data format DAF further improves.

All detection circuits and signal compression methods that can be implemented with appropriate design change by those skilled in the art on the basis of the detection circuit and the signal compression method described above as the embodiment of the present disclosure also belong to the scope of the present disclosure as long as the gist of the present disclosure is included therein.

It is understood that those skilled in the art can conceive of various change examples and correction examples in the category of the idea of the present disclosure and these change examples and correction examples also belong to the scope of the present disclosure. For example, a configuration obtained by executing addition, deletion, or design change of a constituent element as appropriate for the above-described embodiment by those skilled in the art or a configuration obtained by executing addition, omission, or condition change of a step as appropriate for the above-described embodiment by those skilled in the art is also included in the scope of the present disclosure as long as the configuration includes the gist of the present disclosure.

Further, it is understood that what is obvious from the description of the present specification or what can be conceived by those skilled in the art as appropriate concerning other operation and effects provided by the modes described in the present embodiment is naturally provided by the present disclosure.

Various disclosures can be formed by appropriate combinations of a plurality of constituent elements disclosed in the above-described embodiment. For example, several constituent elements may be deleted from all constituent elements depicted in the embodiment. Moreover, constituent elements included in different embodiments may be combined as appropriate.

What is claimed is:

1. A detection circuit comprising:
a plurality of detection elements arranged in a matrix form;
a plurality of scanning lines that extend in a first direction and are arranged in a second direction intersecting the first direction, the scanning lines being connected to a scan circuit;
a plurality of signal lines that extend in the second direction and are arranged in the first direction, the signal lines being connected to a detection circuit; and
a control circuit, wherein
each of the plurality of detection elements is connected to a corresponding scanning line and a corresponding signal line,
the detection circuit is configured to sequentially read out detection values of signals of the plurality of detection elements through the plurality of signal lines, and
the control circuit, when externally outputting a detection value of a signal of a detection element of interest, outputs, as transmission difference data, difference data between a value based on a detection value of a signal of a detection element read out before a detection timing of the detection value of the signal of the detection element of interest and the detection value of the signal of the detection element of interest.

2. The detection circuit according to claim 1, wherein
the control circuit executes
first computation to compute first difference data encoded on a basis of a difference between a detection value of a signal of a corresponding detection element on a corresponding line in a previous frame and the detection value of the signal of the detection element of interest in units of one line in a current frame, and
second computation to compute second difference data encoded on a basis of a difference from an average value of the detection values of the signals of the detection elements included in a predetermined range in the current frame, and
the control circuit selects one difference data with a smaller data amount from either the first difference data or the second difference data, and outputs the selected difference data as the transmission difference data.

3. The detection circuit according to claim 2, wherein
the control circuit outputs the transmission difference data corresponding to one line, in units of the one line in the current frame,
the transmission difference data in units of the one line, the transmission difference data including the one difference data selected, has a basic unit and an expansion unit,
when the difference data of the detection element is within predetermined values, the difference data of the detection element is represented by the basic unit, and
when the difference data of the detection element exceeds the predetermined values, difference data of the predetermined value in the difference data of the detection element is represented by the basic unit, and difference data exceeding the predetermined value in the difference data of the detection element is represented by the expansion unit.

4. The detection circuit according to claim 2, wherein
each detection value is multiplied by a coefficient when the average value of the detection values of the signals of the detection elements read out previously is calculated in the current frame, and
a value of the coefficient is larger for a detection element closer to the detection element of interest.

5. The detection circuit according to claim 3, wherein
data of the one line has, at a beginning, a parameter that defines number of bits of the basic unit and number of bits of the expansion unit.

6. The detection circuit according to claim 5, wherein
the data of the one line further has, at the beginning, a bit indicating whether to refer to data of a detection value of a detection element in the previous frame or to refer to data of a detection value of a signal of a detection element in the current frame.

7. A signal compression method for a detection value of a detection circuit in which a plurality of detection elements are arranged in a matrix form, the signal compression method comprising:
executing first computation of first data encoded on a basis of a difference in a detection value of a signal from corresponding one line in a previous frame in units of one line in a current frame;
executing second computation of second data encoded on a basis of a difference from an average in a predetermined range in the current frame; and
selecting one data with a smaller data amount from either the first data or the second data.

8. The signal compression method according to claim 7, wherein
data in units of one line, the data including the one data selected, has a basic unit and an expansion unit,
when data of the difference is within predetermined values, the data of the difference is represented by the basic unit, and
when the data of the difference exceeds the predetermined values, the data of the difference of the predetermined value in the data of the difference concerning a detection element is represented by the basic unit, and the data of the difference exceeding the predetermined value in the data of the difference concerning the detection element is represented by the expansion unit.

9. The signal compression method according to claim 7, wherein
each detection value is multiplied by a coefficient when an average value of detection values of signals of detection elements read out previously is calculated in the current frame, and a value of the coefficient is larger for an element closer to a detection element of interest.

10. The signal compression method according to claim 8, wherein
the data of the one line has, at a beginning, a parameter that defines number of bits of the basic unit and number of bits of the expansion unit.

11. The signal compression method according to claim 10, wherein
the data of the one line further has, at the beginning, a bit indicating whether to refer to data of a detection value of a signal of a detection element in the previous frame or to refer to data of a detection value of a signal of a detection element in the current frame.

12. The detection circuit according to claim 1, wherein
the value based on a detection value of a signal of a detection element read out before a detection timing of the detection value of the signal of the detection element of interest is an average value of differences in same pixel data between a current frame and a previous frame in a predetermined range previous to the detection element of interest in the current frame.

13. The detection circuit according to claim 12, wherein
the control circuit outputs the transmission difference data corresponding to one line in units of one line in the current frame,
the transmission difference data in units of the one line has a basic unit and an expansion unit,
when the difference data of the detection element is within predetermined values, the difference data of the detection element is represented by the basic unit, and
when the difference data of the detection element exceeds the predetermined values, difference data of the predetermined value in the difference data of the detection element is represented by the basic unit, and difference data exceeding the predetermined value in the difference data of the detection element is represented by the expansion unit.

14. The detection circuit according to claim 13, wherein
the transmission difference data of the one line has, at a beginning, a parameter that defines number of bits of the basic unit and number of bits of the expansion unit.

15. The detection circuit according to claim 14, wherein
the transmission difference data of the one line further has, at the beginning, a bit indicating whether the average value of the differences in the same pixel data between the current frame and the previous frame in the predetermined range previous to the detection element of interest in the current frame is employed or an average value in a reference range in the current frame is employed.

16. The detection circuit according to claim 15, wherein
when predetermined number of predetermined basic units are consecutive, the consecutive basic units are replaced by a consecutiveness compression unit with predetermined number of bits.

17. The detection circuit according to claim 16, wherein
the transmission difference data of the one line further has a bit indicating whether a unit is the basic unit or is the consecutiveness compression unit.
